(19) United States
(12) Patent Application Publication
(10) Pub. No.: US 2018/0248096 A1
(43) Pub. Date: Aug. 30, 2018

(54) THERMOELECTRIC POWER GENERATOR

(71) Applicant: TOYOTA JIDOSHA KABUSHIKI KAISHA, Toyota-shi (JP)

(72) Inventors: Tomoyuki KISHIDA, Nisshin-shi (JP); Takumi KATAYAMA, Toyota-shi (JP); Hideyuki KOMITSU, Toyota-shi (JP); Shinya KITAGAWA, Kariya-city (JP); Takuya MATSUDA, Kariya-city (JP)

(73) Assignee: TOYOTA JIDOSHA KABUSHIKI KAISHA, Toyota-shi (JP)

(21) Appl. No.: 15/855,030

(22) Filed: Dec. 27, 2017

(30) Foreign Application Priority Data
Feb. 28, 2017 (JP) 2017-036672

(51) Int. Cl. H01L 35/02; H01L 35/08; H01L 35/28; H01L 23/473

(52) U.S. Cl. CPC H01L 35/02; H01L 23/473; H01L 35/28; H01L 35/08

(57) ABSTRACT

A thermoelectric power generator has: a pair of thin film sheets that respectively cover a heat receiving side and a cooling side of a thermoelectric element; a resin sealing portion that is superposed with the pair of thin film sheets, in a state of being nipped between the pair of thin film sheets, at a periphery of the thermoelectric element; a heat insulating layer that is disposed at a heat receiving side of the resin sealing portion and that is superposed on one of the pair of thin film sheets; and a presser plate that presses the heat insulating layer toward the resin sealing portion, and that is formed in a stepped shape at which a plate thickness of a region at a side contacting the heat insulating layer is thicker than a plate thickness of a fixed region that is fixed by a fixing portion.

### CROSS-REFERENCE TO RELATED APPLICATION

This application claims priority under 35 USC 119 from Japanese Patent Application No. 2017-036672 filed Feb. 28, 2017, the disclosure of which is incorporated by reference herein.

### BACKGROUND

### Technical Field

The present invention relates to a thermoelectric power generator.

Japanese Patent Application Laid-Open (JP-A) No. 2007-165560 discloses a structure in which the entire periphery of a thermoelectric module is surrounded by a heat insulating material such that the region between a high-temperature portion and a cooling unit is insulated, and positioning of the thermoelectric module is carried out by this heat insulating material. Note that JP-A No. 2016-009787 discloses a thermoelectric power generating module that has a heat insulating sheet layer between a heat receiving plate and a sealing portion of a laminate sheet of a thermoelectric power generating element.

Sealing of the thermoelectric module is not considered in the structure disclosed in JP-A No. 2007-165560, and there is room for improvement.

### SUMMARY

The present invention provides a thermoelectric power generator that can suppress the exposure of a resin sealing portion to high temperatures.

A thermoelectric power generator of a first aspect of the present invention has: a pair of thin film sheets that respectively cover a heat receiving side and a cooling side of a thermoelectric element; a resin sealing portion that is superposed with the pair of thin film sheets, in a state of being nipped between the pair of thin film sheets, at a periphery of the thermoelectric element; a heat insulating layer that is disposed at a heat receiving side of the resin sealing portion and that is superposed on one of the pair of thin film sheets; and a presser plate that presses the heat insulating layer toward the resin sealing portion, and that is formed in a stepped shape at which a plate thickness of a region at a side contacting the heat insulating layer is thicker than a plate thickness of a fixed region that is fixed by a fixing portion.

In accordance with the first aspect, the heat receiving side and the cooling side of the thermoelectric element are respectively covered by the pair of thin film sheets. At the periphery of the thermoelectric element, the resin sealing portion is superposed with the pair of thin film sheets in state of being nipped between the pair of thin film sheets. At the heat receiving side of the resin sealing portion, the heat insulating layer is superposed on one of the pair of thin film sheets. Moreover, the presser plate that presses the heat insulating layer is provided. The presser plate is formed in a stepped shape at which the plate thickness of the region, which is at the side that contacts the heat insulating layer, is thicker than the plate thickness of the fixed region that is fixed by the fixing portion. Due thereto, the heat insulating layer is pressed toward the resin sealing portion by the region, which is at the side where the plate thickness is thick, of the presser plate, and the presser plate is fixed by the fixing portion at the fixed region where the plate thickness of the presser plate is thin. In such a structure, because the presser plate has a stepped shape, the presser plate is provided with a difference in ease of flexing, and the fixed region where the plate thickness of the presser plate is thin flexes more moderately due to the fastening of the fixing portion, and the heat insulating layer is pressed more reliably toward the resin sealing portion by the region of the presser plate where the plate thickness is thick. Therefore, the heat insulating layer can appropriately be made to fit tightly to the resin sealing portion side, and the resin sealing portion being exposed to high temperatures is suppressed.

In a thermoelectric power generator of a second aspect of the present invention, in the first aspect, the presser plate is formed in a shape of a frame that entirely surrounds the periphery of the thermoelectric element.

In accordance with the second aspect, the presser plate is formed in the shape of a frame that surrounds the entire periphery of the thermoelectric element. The heat insulating layer is pressed toward the resin sealing portion by the frame-shaped presser plate at the periphery of the thermoelectric element. Therefore, the heat insulating layer can be pressed toward the resin sealing portion by the presser plate also at the region where the presser plate cannot be fixed by the fixing portion (the region other than the fixed region that is fixed by the fixing portion).

In a thermoelectric power generator of a third aspect of the present invention, in the second aspect, a plate thickness of a region at the presser plate which includes an inner side edge portion is thicker than a plate thickness of the fixed region.

In accordance with the third aspect, the plate thickness of the region at the presser plate, which includes the inner side edge portion is thicker than the plate thickness of the fixed region. Due thereto, by a simple structure, at the region of the presser plate where the plate thickness is thick and that includes the inner side edge portion, the heat insulating layer can be pressed toward the resin sealing portion, and the presser plate can be fixed at the fixed region which is a region other than the inner side edge portion of the presser plate.

In a thermoelectric power generator of a fourth aspect of the present invention, in the second aspect, the presser plate has, at at least one side of the frame shape, a path that supplies and discharges cooling water to and from the cooling side of the thermoelectric element, and the presser plate is fixed by the fixing portion at a side that does not include the path.

In accordance with the fourth aspect, the presser plate has, at at least one side of the frame shape, the path that supplies and discharges cooling water to and from the cooling side of the thermoelectric element. The presser plate is fixed by the fixing portion at a side that does not include the path. Due thereto, the presser plate can be fixed at a region of the presser plate which region does not interfere with the path that supplies and discharges the cooling water.

### BRIEF DESCRIPTION OF THE DRAWINGS

Exemplary embodiments of the present invention will be described in detail based on the following figures, wherein:

FIG. 1 is a cross-sectional view showing a fixed portion side of a thermoelectric power generator relating to an embodiment;

FIG. 2 is an exploded perspective view showing the thermoelectric power generator relating to the embodiment;

FIG. 3 is a perspective view showing a state in which the thermoelectric power generator relating to the embodiment is assembled;

FIG. 4A is a cross-sectional view showing a side along a length direction of a presser plate;

FIG. 4B is a cross-sectional view showing a side along a direction orthogonal to the length direction of the presser plate; and

FIG. 5 is a cross-sectional view showing a fixed portion side of a thermoelectric power generator relating to a comparative example.

### DETAILED DESCRIPTION

An embodiment of the present invention will be described in detail on the basis of the drawings. Note that arrow UP that is shown appropriately in these drawings indicates the upper side of a vehicle in which a thermoelectric power generator is disposed. Further, in order to make the directions clear, in these drawings, the direction shown by arrow W is the width direction of the thermoelectric power generator for convenience, and the direction shown by arrow D is the depth direction of the thermoelectric power generator for convenience.

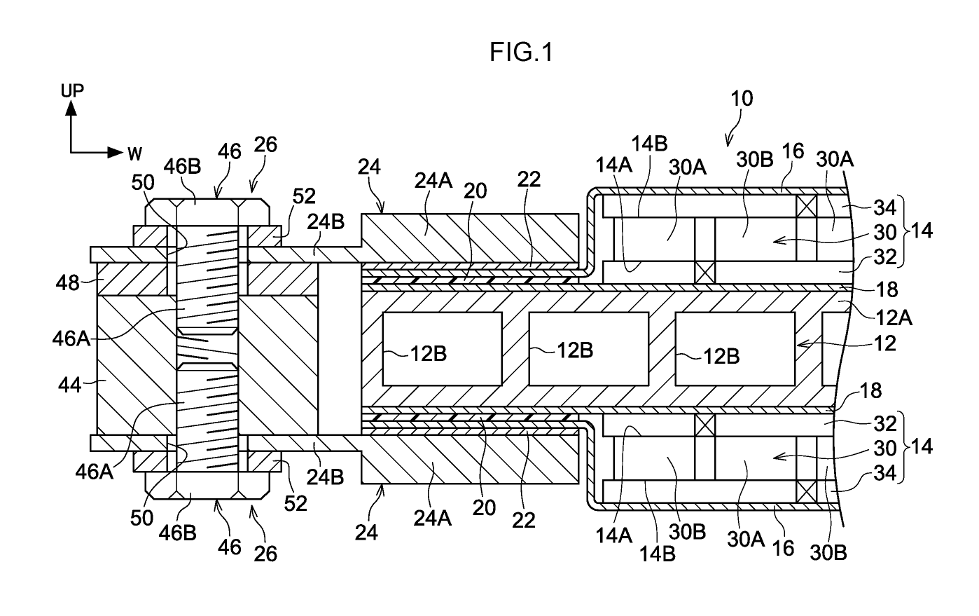

The thermoelectric power generator relating to the embodiment is described hereinafter by using FIG. 1 through FIG. 4A and FIG. 4B.

A portion of a thermoelectric power generator 10 of the embodiment is shown in a cross-sectional view in FIG. 1. As shown in FIG. 1, the thermoelectric power generator 10 has a pair of upper and lower thermoelectric power generating modules 14 that serve as thermoelectric elements and are disposed at the upper side and the lower side in the vertical direction of a cooling water pipe 12. The portion of the thermoelectric power generating module 14 that is at the cooling water pipe 12 side is cooling side 14A, and the portion of the thermoelectric power generating module 14 that is at the side opposite the cooling water pipe 12 is a heat receiving side 14B. The pair of upper and lower thermoelectric power generating modules 14 are formed so as to be symmetrical vertically. The thermoelectric power generator 10 has laminate sheets 16, 18 that serve as pairs of thin-film sheets and that respectively cover the heat receiving sides 14B and the cooling sides 14A of the thermoelectric power generating modules 14. The one laminate sheets 16 are disposed at the heat receiving sides 14B of the thermoelectric power generating modules 14 (the upper side and the lower side of the thermoelectric power generator 10 in the present embodiment). The other laminate sheets 18 are disposed at positions of contacting the cooling water pipe 12 that are the cooling sides 14A of the thermoelectric power generating modules 14.

The thermoelectric power generator 10 has, at the peripheries of the thermoelectric power generating modules 14 (at the sides of the thermoelectric power generating modules 14 shown in FIG. 1), resin sealing portions 20 that are layer-shaped and are superposed with the pairs of laminate sheets 16, 18 in states of being nipped between the pairs of laminate sheets 16, 18. The thermoelectric power generator 10 has heat insulating sheets 22 that serve as heat insulating layers and are disposed at the heat receiving sides of the resin sealing portions 20 (the same sides as the heat receiving sides 14B of the thermoelectric power generating modules 14), and are superposed on the one laminate sheets 16 among the laminate sheets 16, 18. Moreover, the thermoelectric power generator 10 has a pair of upper and lower presser plates 24 that press the heat insulating sheets 22 against the resin sealing portions 20, and fixing portions 26 that respectively fix the pair of upper and lower presser plates 24. The thermoelectric power generator 10 is substantially symmetrical vertically.

As shown in FIG. 1, the thermoelectric power generating module 14 has plural semiconductor elements 30 that are disposed so as to be lined-up, and a pair of metal plate electrodes 32, 34 that are respectively disposed at the surface at the one side and the surface at the other side of the semiconductor elements 30 (in the present embodiment, at the upper and lower surfaces of the semiconductor elements 30). The semiconductor elements 30 are structured by, for example, Peltier elements that are formed from a pair of an N-type semiconductor element 30A and a P-type semiconductor element 30B, and the N-type semiconductor elements 30A and the P-type semiconductor elements 30B are disposed alternately along the plane direction. The metal plate electrodes 32, 34 are connected in series to the N-type semiconductor elements 30A and the P-type semiconductor elements 30B. In the present embodiment, the surfaces at the heat receiving sides 14B of the N-type semiconductor elements 30A and the P-type semiconductor elements 30B are connected to the one metal plate electrode 34, and the surfaces at the cooling sides 14A of the N-type semiconductor elements 30A and the P-type semiconductor elements 30B are connected to the other metal plate electrode 32.

Although not illustrated, at the thermoelectric power generator 10, the heat receiving side 14B of the thermoelectric power generating module 14 is disposed at a position to which heat from exhaust gas, which passes through an unillustrated exhaust pipe of the vehicle, is transferred. In the present embodiment, the heat receiving side 14B of the thermoelectric power generating module 14 is disposed via a heat transmitting portion (not illustrated) that is provided adjacent to the exhaust pipe of the vehicle. High-temperature gas or the like for example is sealed within the heat transmitting portion. The thermoelectric power generating module 14 can be made to generate electric power due to the Seebeck effect, which corresponds to the temperature difference between the heat receiving sides 14B and the cooling sides 14A of the semiconductor elements 30, being caused. The temperature of the high-temperature gas that is sealed in the heat transmitting portion is, for example, approximately 300° C. Note that, instead of the above-described structure, there may be a structure in which the thermoelectric power generating modules 14 of the thermoelectric power generator 10 are disposed directly within the exhaust pipe.

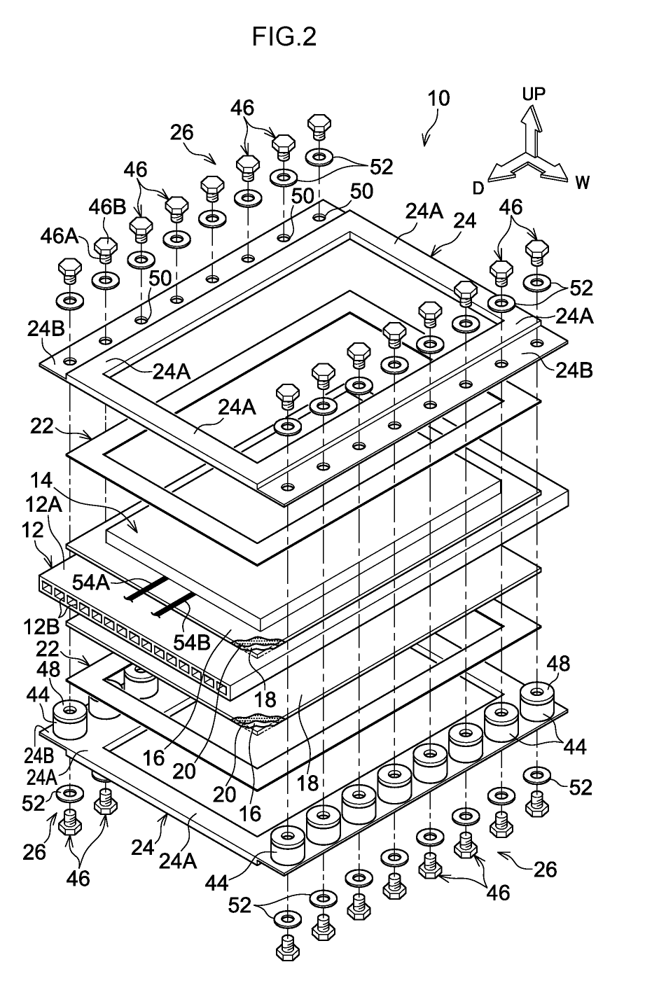

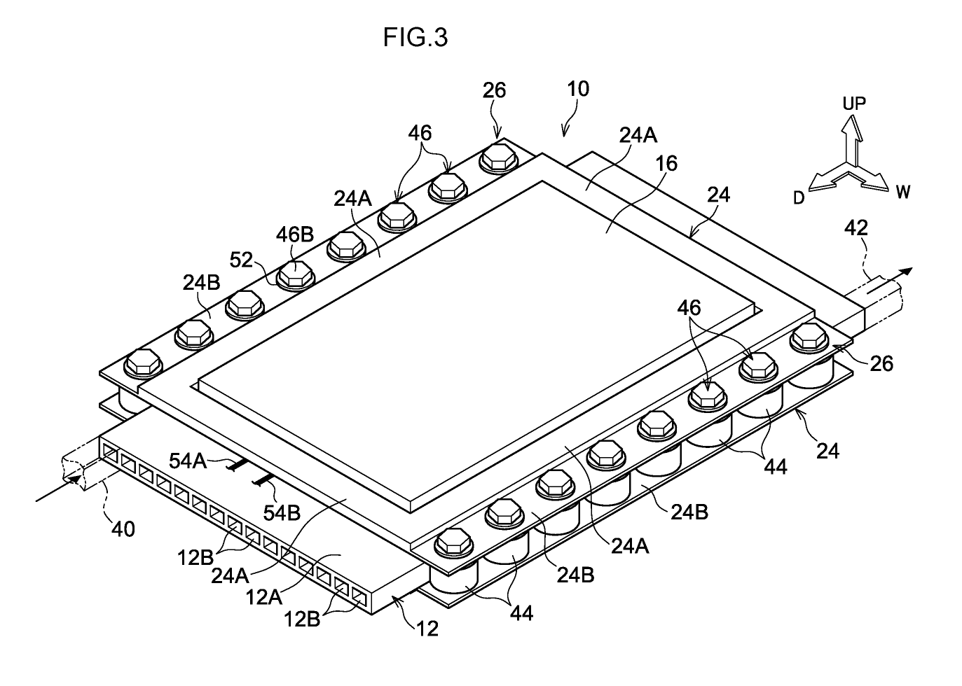

The thermoelectric power generator 10 is shown in an exploded perspective view in FIG. 2, and the thermoelectric power generator 10 in an assembled state is shown in a perspective view in FIG. 3.

As shown in FIG. 1 through FIG. 3, the cooling water pipe 12 has plural cooling water flow-through portions 12B at the interior of a plate-shaped member 12A that is substantially rectangular. In the present embodiment, the plural cooling water flow-through portions 12B are disposed so as to be lined-up such that the length direction of the plate-shaped member 12A is the direction of flow within the plural cooling water flow-through portions 12B. A path 40 that supplies cooling water to the cooling water flow-through portions 12B, and a path 42 that discharges cooling water from the cooling water flow-through portions 12B, are connected to the cooling water pipe 12 (see FIG. 3). Due thereto, cooling water is supplied from the path 40 to the cooling water flow-through portions 12B and flows-through the cooling water flow-through portions 12B, and thereafter, the cooling water is discharged-out to the path 42. Note that the structures of the path 40 and the path 42 can be changed.

As shown in FIG. 1, the laminate sheet 16 is disposed so as to contact the one metal plate electrode 34 that is disposed at the heat receiving side 14B of the thermoelectric power generating module 14. The laminate sheet 16 is structured by, for example, a sheet (a layered sheet) in which an aluminum thin film is laminated on a resin thin film, and is disposed such that the resin thin film side thereof contacts the metal plate electrode 34. Further, the laminate sheet 18 is provided so as to contact the other metal plate electrode 32 that is disposed at the cooling side 14A of the thermoelectric power generating module 14. The laminate sheet 18 is structured by, for example, a sheet (a layered sheet) in which an aluminum thin film is laminated on a resin thin film, and is disposed such that the resin thin film side thereof contacts the metal plate electrode 32. Lead wires 54A, 54B for taking the generated electric power out are connected to the metal plate electrode 34 and the metal plate electrode 32 (see FIG. 2 and FIG. 3).

As shown in FIG. 1 and FIG. 2, the resin sealing portion 20 is disposed between the laminate sheet 16 and the laminate sheet 18 at the periphery of the thermoelectric power generating module 14 (at the side of the thermoelectric power generating module 14 shown in FIG. 1). The resin sealing portion 20 is provided in order to seal between the high-temperature gas at the exterior and the thermoelectric power generating module 14 at the interior in order to prevent oxidative degradation of the semiconductor elements 30 of the thermoelectric power generating module 14. The surfaces at the both sides of the resin sealing portion 20 are joined to the laminate sheet 16 and the laminate sheet 18.

As shown in FIG. 1 and FIG. 2, the heat insulating sheet 22 is structured as a frame-shaped member, and is disposed at the periphery of the thermoelectric power generating module 14 (the side of the thermoelectric power generating module 14 shown in FIG. 1). The heat insulating sheet 22 is disposed so as to cover the entire surface of the resin sealing portion 20 via the laminate sheet 16. Due to the heat insulating sheet 22 contacting the resin sealing portion 20 via the laminate sheet 16, the resin sealing portion 20 being heated to a temperature that exceeds the heat resistance temperature thereof is suppressed. The heat resistance temperature of the resin sealing portion 20 is, for example, approximately 150° C.

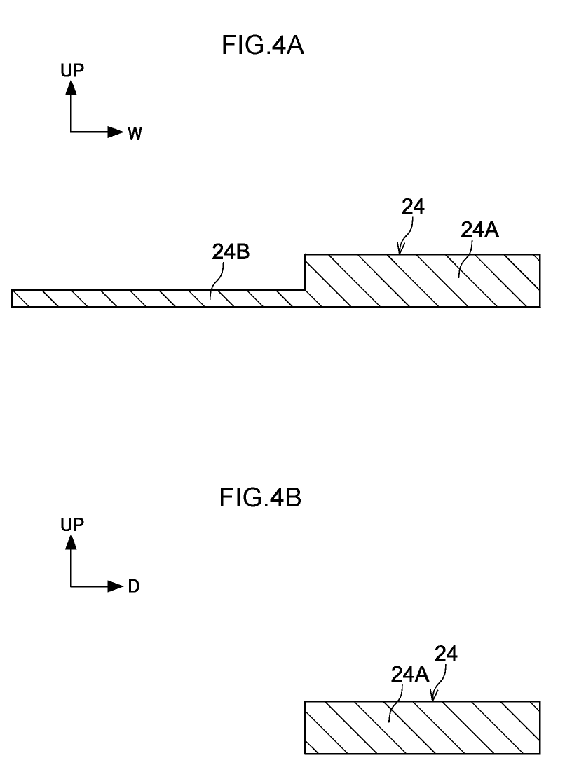

As shown in FIG. 1 through FIG. 3, the presser plate 24 is formed by a substantially rectangular, frame-shaped member, and is disposed so as to surround the entire periphery of the thermoelectric power generating module 14 (see FIG. 2 and FIG. 3). At least a portion of the presser plate 24 is disposed at a position that covers the heat insulating sheet 22. More concretely, the presser plate 24 has a thick plate portion 24A at which the plate thickness of the region at the side that contacts the heat insulating sheet 22 is thick, and a thin plate portion 24B at which the plate thickness of a fixed region at which the presser plate 24 is fixed is made to be thinner than that of the thick plate portion 24A. Namely, the presser plate 24 is formed in a stepped shape that has the thick plate portion 24A and the thin plate portion 24B. In the present embodiment, at the presser plate 24, the sides that run along the length direction are formed in stepped shapes having the thick plate portion 24A and the thin plate portion 24B, and the thick plate portion 24A is provided at a position that includes the inner side edge portion of the presser plate 24 (see FIG. 2 and FIG. 4A). Further, at the presser plate 24, the sides that run along the direction orthogonal to the length direction are structured only by the thick plate portion 24A (see FIG. 2 and FIG. 4B).

The presser plates 24 are disposed such that the thick plate portions 24A contact the heat insulating sheets 22, and, by the thick plate portions 24A, press the heat insulating sheets 22 toward the resin sealing portions 20 via the laminate sheets 16. The thin plate portions 24B of the presser plates 24 are fixed by the fixing portions 26. The fixing portions 26 have plural nuts 44 that are disposed between the pair of upper and lower presser plates 24, and plural bolts 46 that are screwed-together respectively with the one sides and the other sides in the axial directions of the nuts 44.

More concretely, as shown in FIG. 1 and FIG. 2, the nuts 44 and shims 48, which are interposed between the nuts 44 and one of the presser plates 24 in accordance with the distance between the pair of upper and lower presser plates 24, are disposed between the pair of upper and lower presser plates 24 (see FIG. 1). The bolt 46 has a shaft portion 46A that has a male screw portion, and a head portion 46B that is provided at one end portion of the shaft portion 46A. Plural through-holes 50, through which the shaft portions 46A of the bolts 46 are passed respectively, are provided in the thin plate portions 24B of the presser plates 24. In the present embodiment, the plural through-holes 50 are formed in rows along the length direction of the thin plate portions 24B of the presser plates 24.

The shaft portions 46A of the bolts 46 are passed-through the through-holes 50 of the thin plate portions 24B via washers 52 from the side of one of the presser plates 24 (in FIG. 1, the upper presser plate 24), and the male screw portions of the shaft portions 46A are screwed-together with female screw portions of the nuts 44. Further, the shaft portions 46A of the bolts 46 are passed-through the through-holes 50 of the thin plate portion 24B via the washers 52 from the side of the other (in FIG. 1, the lower) presser plate 24, and the male screw portions of the shaft portions 46A are screwed-together with the female screw portions of the nuts 44. Due thereto, the pair of upper and lower presser plates 24 are fastened and fixed by the bolts 46 at the upper side, the bolts 46 at the lower side, and the nuts 44.

Operation and effects of the thermoelectric power generator 10 of the present embodiment are described next.

At the thermoelectric power generator 10, the heat receiving side 14B and the cooling side 14A of the thermoelectric power generating module 14 are covered by the pair of laminate sheets 16, 18, respectively. At the periphery of the thermoelectric power generating module 14, the resin sealing portion 20 is superposed with the pair of laminate sheets 16, 18 in a state of being nipped between the pair of laminate sheets 16, 18. At the heat receiving side of the resin sealing portion 20, the heat insulating sheet 22 is superposed on the one laminate sheet 16. Further, the presser plate 24 that presses the heat insulating sheet 22 toward the resin sealing portion 20 is provided. The presser plate 24 is formed in a stepped shape that has the thick plate portion 24A at which the plate thickness of the region at the side that contacts the heat insulating sheet 22 is thick, and the thin plate portion 24B at which the plate thickness of the fixed regions where the presser plate 24 is fixed by the fixing portions 26 is made to be thinner than that of the thick plate portion 24A.

In this thermoelectric power generator 10, the heat insulating sheets 22 are pressed toward the resin sealing portions 20 by the thick plate portions 24A of the presser plates 24, and the upper and lower presser plates 24 are fastened and fixed to the nuts 44 by the bolts 46 of the fixing portions 26 at the thin plate portions 24B of the presser plates 24. In this structure, because the presser plates 24 have stepped shapes, there is a difference in the ease of flexing at the presser plates 24, and the thin plate portions 24B of the presser plates 24 flex more moderately due to the fastening by the bolts 46 and the nuts 44 of the fixing portions 26. Further, at the thick plate portions 24A of the presser plates 24, the heat insulating sheets 22 are pressed more reliably toward the resin sealing portions 20. Therefore, the heat insulating sheets 22 are appropriately made to fit tightly to the resin sealing portion 20 sides, and the resin sealing portions 20 being exposed to high temperature is suppressed.

Further, at the thermoelectric power generator 10, the presser plates 24 are formed in the shapes of frames that surround the entire peripheries of the thermoelectric power generating modules 14. Due thereto, the heat insulating sheets 22 are pressed toward the resin sealing portions 20 by the presser plates 24 at the peripheries of the thermoelectric power generating modules 14. Therefore, the heat insulating sheets 22 can be pressed by the presser plates 24 toward the resin sealing portions 20 even at the regions at the sides that are orthogonal to the length direction of the presser plates 24, i.e., the regions where the presser plates 24 cannot be fixed by the fixing portions 26.

Further, in the thermoelectric power generator 10, there is a structure in which the plate thickness of the thick plate portions 24A that include the inner side edge portions of the presser plates 24 is thicker than the plate thickness of the thin plate portions 24B that are fixed by the fixing portions 26. Due thereto, by a simple structure, the heat insulating sheets 22 can be pressed toward the resin sealing portions 20 by the thick plate portions 24A that include the inner side edge portions of the presser plates 24, and the presser plates 24 can be fixed by the fixing portions 26 at the thin plate portions 24B of the presser plates 24.

Moreover, in the thermoelectric power generator 10, the presser plates 24 have, at at least one side of the frame shapes (in the present embodiment, at the two sides at the sides that are orthogonal to the length direction), the path 40, which supplies cooling water to the cooling sides 14A of the thermoelectric power generating modules 14, and the path 42 that discharges the cooling water out. Further, the presser plates 24 are fixed by the fixing portions 26 at the sides of the presser plates 24 that do not include the paths 40, 42 (in the present embodiment, the two sides that run along the length direction). Due thereto, the presser plates 24 can be fixed by the fixing portions 26 at regions of the presser plates 24 that do not interfere with the path 40 that supplies the cooling water and the path 42 that discharges the cooling water.

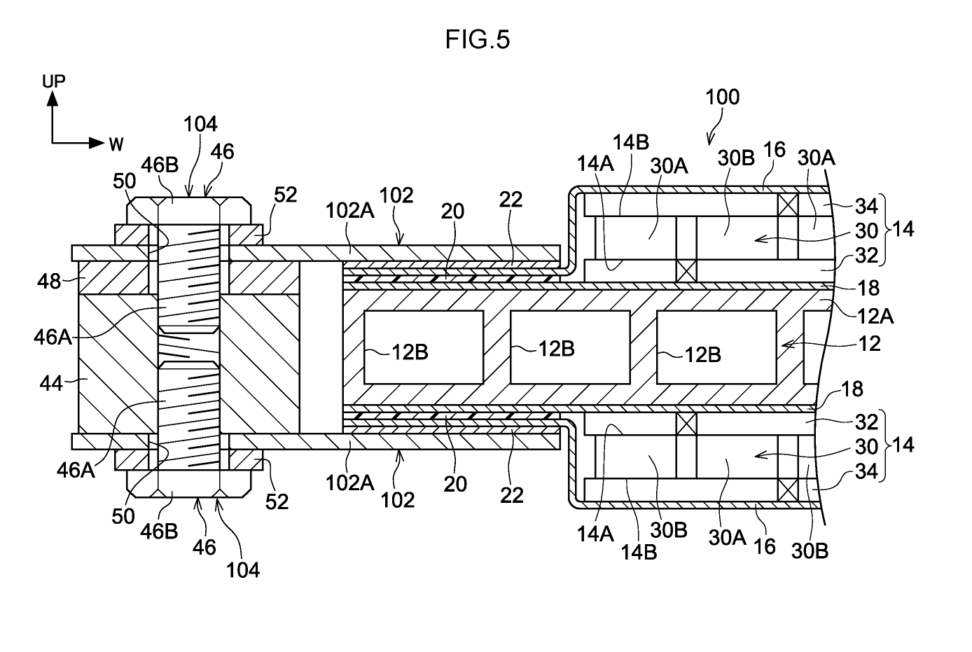

A portion of a thermoelectric power generator 100 of a comparative example is shown in FIG. 5. Note that structural portions that are the same as those of the thermoelectric power generator 10 of the above-described embodiment are denoted by the same reference numerals, and description thereof is omitted.

As shown in FIG. 5, the thermoelectric power generator 100 has a pair of upper and lower presser plates 102 that press the heat insulating sheets 22 toward the resin sealing portions 20, and fixing portions 104 that fix the pair of upper and lower presser plates 102, respectively. The presser plate 102 is structured by a plate-shaped portion 102A that is that is formed from a thin plate whose thickness is substantially uniform. One end portion side of the plate-shaped portion 102A of the presser plate 102 is disposed at a position that covers the heat insulating sheet 22. The thickness of the plate-shaped portion 102A is set to be substantially the same thickness as that of the thin plate portion 24B of the presser plate 24 that is used in the thermoelectric power generator 10 of the embodiment.

Due to one end portion side of the plate-shaped portion 102A of the presser plate 102 contacting the heat insulating sheet 22, the heat insulating sheet 22 is pressed toward the resin sealing portion 20 via the laminate sheet 16. Further, the other end portion side of the plate-shaped portion 102A of the presser plate 102 is fixed by the fixing portion 104. In the same way as in the thermoelectric power generator 10 of the embodiment, the fixing portion 104 has the plural nuts 44 that are disposed between the pair of upper and lower presser plates 102, and the plural bolts 46 that are screwed-together respectively with the axial direction one sides and other sides of the nuts 44, and the like.

In this thermoelectric power generator 100, the heat insulating sheets 22 are pressed toward the resin sealing portions 20 via the laminate sheets 16 by the plate-shaped portions 102A, which are formed from thin plates, of the presser plates 102. At the time when the presser plates 102 are fastened by the bolts 46 of the fixing portions 104, if the thickness of the plate-shaped portions 102A is thin, the presser plates 102 flex and partially contact the heat insulating sheets 22, and there is the possibility that the heat insulating sheets 22 will float-up from the resin sealing portions 20. In this case, because the heat insulating sheets 22 cannot be made to fit tightly to the entire surfaces at the resin sealing portion 20 sides, there is the possibility that the resin sealing portions 20 will exceed the heat resistance temperature, and that the physical properties of the resin sealing portions 20 will change, and the sealing function thereof will deteriorate.

In contrast, in the thermoelectric power generator 10 of the present embodiment, the thin plate portions 24B of the presser plates 24 flex moderately due to the fastening of the bolts 46 and the nuts 44 of the fixing portions 26, and the heat insulating sheets 22 are more reliably pressed toward the resin sealing portions 20 by the thick plate portions 24A of the presser plates 24. Therefore, the heat insulating sheets 22 are appropriately made to fit tightly to the resin sealing portion 20 sides, and the resin sealing portions 20 being exposed to high temperatures can be suppressed.

Note that, in the thermoelectric power generator 10 of the above-described embodiment, the fixing portions 26 are provided along the length direction of the presser plates 24, but the present invention is not limited to this structure. For example, there may be a structure in which the fixing portions are provided along the direction orthogonal to the length direction of the presser plates. Further, although the presser plates 24 are frame-shaped in the above-described embodiment, the presser plates can be changed to another shape.

Further, in the thermoelectric power generator 10, the structure of the thermoelectric power generating modules 14 is not limited to the structure of the above-described embodiment, and can be changed. Further, in the thermoelectric power generator 10 of the above-described embodiment, the pair of thermoelectric power generating modules 14 are provided at the both sides in the vertical direction of the cooling water pipe 12, but there may be a structure in which a thermoelectric power generating module is provided at either one side in the vertical direction of the cooling water pipe 12.

Moreover, the thermoelectric power generator 10 of the above-described embodiment is disposed such that the direction orthogonal to the plane direction of the presser plates 24 is the vertical direction. However, the present invention is not limited to this structure, and the direction in which the thermoelectric power generator is disposed can be changed. For example, the thermoelectric power generator may be disposed such that the plane direction of the presser plates 24 intersects the vertical direction, or may be disposed such that the plane direction of the presser plates 24 is the vertical direction.

What is claimed is:

1. A thermoelectric power generator comprising:
a pair of thin film sheets that respectively cover a heat receiving side and a cooling side of a thermoelectric element;
a resin sealing portion that is superposed with the pair of thin film sheets, in a state of being nipped between the pair of thin film sheets, at a periphery of the thermoelectric element;
a heat insulating layer that is disposed at a heat receiving side of the resin sealing portion and that is superposed on one of the pair of thin film sheets; and
a presser plate that presses the heat insulating layer toward the resin sealing portion, and that is formed in a stepped shape at which a plate thickness of a region at a side contacting the heat insulating layer is thicker than a plate thickness of a fixed region that is fixed by a fixing portion.

2. The thermoelectric power generator of claim 1, wherein the presser plate is formed in a shape of a frame that entirely surrounds the periphery of the thermoelectric element.

3. The thermoelectric power generator of claim 2, wherein a plate thickness of a region at of the presser plate which includes an inner side edge portion is thicker than a plate thickness of the fixed region.

4. The thermoelectric power generator of claim 2, wherein:
the presser plate has, at at least one side of the frame shape, a path that supplies and discharges cooling water to and from the cooling side of the thermoelectric element, and
the presser plate is fixed by the fixing portion at a side that does not include the path.

5. The thermoelectric power generator of claim 2, wherein, at the presser plate, sides along a length direction of the frame shape are formed in stepped shapes, and sides along a direction orthogonal to the length direction of the frame shape have a plate thickness equal to that of the region at the side contacting the heat insulating layer.
